(19) United States
(12) Patent Application Publication
(10) Pub. No.: US 2007/0111456 A1
(43) Pub. Date: May 17, 2007

(54) Power semiconductor device and method of fabricating the same

(75) Inventors: Hyung-Tae Ji, Hwaseong-si (KR); Seung-Rok Lee, Hwaseong-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/598,674

(22) Filed: Nov. 14, 2006

(30) Foreign Application Priority Data
Nov. 15, 2005 (KR) 10-2005-0109250

(51) Int. Cl. H01L 21/84; H01L 21/336

(52) U.S. Cl. 438/291; 438/151

(57) ABSTRACT

A power semiconductor device may include a substrate having a first conductivity type. A drift region having a first conductivity type may be formed on an upper surface of the substrate. A body region having a second conductivity type may be formed on a surface of the drift region. A source region having the first conductivity type may be formed in the body region and may be spaced apart from the drift region. A gate electrode may be formed on the upper surface of the drift region. A drain electrode may be formed on a bottom surface of the substrate and may extending into the substrate to a depth.

### PRIORITY STATEMENT

This U.S. non-provisional application claims benefit of priority under 35 U.S.C. § 119 from Korean Patent Application 2005-109250, filed on Nov. 15, 2005 in the Korean Intellectual Property Office (KIPO), the entire contents of which are hereby incorporated by reference.

### BACKGROUND

1. Field

Example embodiments relate to a power semiconductor device and a method of fabricating the same, for example, a power semiconductor device used to switch or amplify power and a method the same.

2. Description of Related Art

Power semiconductor devices may be used to switch or amplify higher voltages, for example, ranging from dozens to hundreds of volts. Power semiconductor devices may be used as DMOS (Double-diffused Metal Oxide Semiconductor) structural transistors for vertical operation. Power semiconductor devices may require a low on-resistance to reduce power loss.

FIG. 1 is a cross-sectional view of a conventional power semiconductor device having a DMOS structure.

Referring to FIG. 1, a conventional power semiconductor device may include an n-epitaxial layer 20 formed on an upper surface of n+substrate 10 and a drain electrode 38 formed on a bottom surface of the n+substrate 10. A p-type body region 30 may be formed on a surface of the n-epitaxial layer 20. An n+source 34 and a p+pickup 32 may be formed in the body region 30. The n+source 34 may be spaced apart from the n-epitaxial layer 20. A gate electrode 36 may be formed on the body region 30. A gate insulator (not shown) may be interposed between the gate electrode 36 and the body region 30. The gate electrode 36 may have at least one end aligned with the edge of a source 34 and may overlap a p-type body region 30.

If a positive (+) bias is applied to the gate electrode 36, an inversion channel may be formed on a surface of the p-type body region 30 between the source 34 and the n-epitaxial layer 20. Thus, the source 34 and the drain electrode 38 may be electrically connected to result in a charge migration. The n-epitaxial layer 20 may correspond to a drift region, for example, a region where charge may be drifted. To obtain a higher breakdown voltage, it may be necessary to increase a width of the n-epitaxial layer 20 and/or lightly dope the n-epitaxial layer 20. For these reasons, various methods have been studied to increase the on-resistance without limiting a thickness and a doping concentration of an n-epitaxial layer.

FIG. 2 is a cross-sectional view of a resist path affecting the on-resistance in a conventional power semiconductor device. FIG. 3 is a circuit diagram of the main resistors between a source and a drain electrode.

Referring to FIG. 2 and FIG. 3, if positive (+) bias is applied to a gate electrode 36, an inversion channel may be formed on a surface of a p-type body region 30 below the gate electrode 36. Electrons may migrate to the drain electrode 38 from a source 34 via the inversion channel, an n-epitaxial layer 20, and/or an n+substrate 10. If a current path between the source 34 and the drain electrode 38 is connected, the on-resistance may be represented as a series of resistors, for example, a source contact resistor R_{cs}, a source diffusion resistor Rₙ₊, a channel resistor R_{ch}, an epitaxial resistor Rₑₚᵢ, a substrate resistor R_{sub}, and/or a drain contact resistor R_{cd}. Among these resistors, only changing values of the resistance of the source diffusion resistor Rₙ₊, the channel resistor R_{ch}, and/or the epitaxial resistor Rₑₚᵢ may have an effect on the operation characteristics of the power semiconductor device. Because resistance values of the source contact resistor R_{cs} and the drain contact resistor R_{cd} are relatively small, changing the values of the source contact resistor R_{cs} and the drain contact resistor R_{cd} may have little or no effect on the on-resistance reduction. Accordingly, a method for reducing on-resistance without having an effect on the operation characteristics of a power semiconductor device may include reducing the resistance of a substrate resistor R_{sub}.

A method for reducing the resistance of the substrate R_{sub} may include using a higher concentration doped substrate. However, defects may arise when fabricating a higher concentration doped substrate.

A method for reducing the substrate resistor R_{sub} may include reducing a thickness of the substrate before the drain electrode 38 is formed. For example, a bottom surface of the substrate 10 may be polished. The power semiconductor device may be formed having a thickness of a substrate ranging from about 80 to 150 micrometers. However, there may be problems with a thinner substrate, for example, the substrate may crack and/or the wafer may be bent during subsequent processes. In a large-diameter wafer, for example, a wafer of 300 millimeters, the problem may be more serious.

### SUMMARY

Example embodiments may provide a power semiconductor device and method of fabricating the same, which may reduce the on-resistance of the power semiconductor device.

Example embodiments may provide a power semiconductor device and method of fabricating the same, which may reduce the resistance of the substrate without thinning the thickness of the substrate or raising an impurity concentration.

In an example embodiment, a power semiconductor device may include a substrate having a first conductivity type. A drift region having the first conductivity type in lower concentration may be formed on an upper surface of the substrate. A body region having a second conductivity type may be formed on an upper surface of the drift region. A source region having the first conductivity type may be formed in the body region and may be spaced apart from the drift region. A gate electrode may be formed on the upper surface of the drift region. A drain electrode may be formed on a bottom surface of the substrate and may extend into the substrate to a depth.

According to an example embodiment, the drain electrode may extend into the substrate to fill at least one trench formed in the bottom surface of the substrate.

According to an example embodiment, the drain electrode may be a metal layer.

According to an example embodiment, the drain electrode may include a plate covering the bottom surface of the substrate and at least one vertical extension that may extend to a depth in the substrate.

According to an example embodiment, the first conductivity may be an n-type and the second conductivity type may be a p-type.

According to an example embodiment, an edge of the gate electrode may be aligned with the source region and the gate electrode may overlap the body region.

In an example embodiment, a method of fabricating a power semiconductor device may include forming a drift region on an upper surface of a semiconductor substrate; forming a body region at a surface of the drift region; forming a source region in the body region; forming a gate insulator having at least one edge aligned with an edge of the source region and overlapping the body region; forming a gate electrode aligned with an edge of the source region and overlapping the body region at the gate insulator; forming a trench in the bottom surface of the semiconductor substrate; and forming a drain electrode on the bottom surface of the semiconductor substrate to fill the trench.

### BRIEF DESCRIPTION OF THE DRAWINGS

Example non-limiting embodiments will be described with reference to the accompanying drawings.

FIG. 1 is a cross-sectional view of a conventional DMOS type electric power device.

FIG. 2 is a cross-sectional view of a resist path of a conventional DMOS type electric power device.

FIG. 3 is a circuit diagram of the main resistors between a source and a drain in a conventional electric power device.

FIG. 4 is a cross-sectional view of a power semiconductor device according to an example embodiment.

FIG. 5 is a cross-sectional view of a power semiconductor device according to an example embodiment.

FIGS. 6 through 9 are plan views of a drain electrode of a power semiconductor device according to example embodiments.

FIGS. 10 through 13 are cross-sectional views of a method of fabricating a power semiconductor device according to example embodiments.

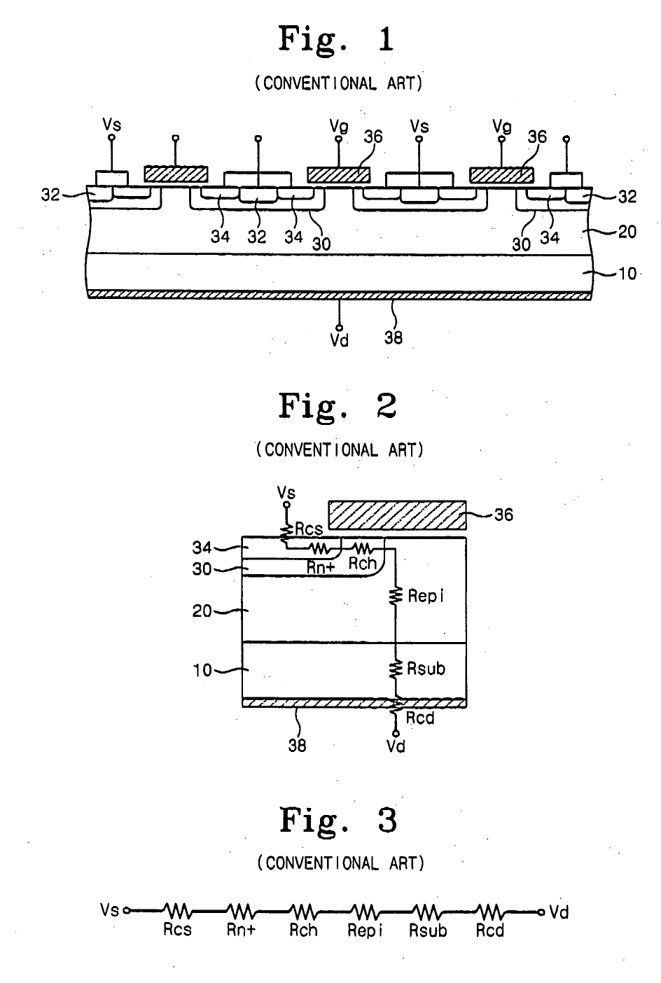

### DESCRIPTION OF EXAMPLE EMBODIMENTS

Example embodiments will now be described more fully hereinafter with reference to the accompanying drawings, in which preferred embodiments of the invention are shown. Example embodiments, however, may be embodied in many different forms and should not be construed as limited to the example embodiments set forth herein. Rather, the example embodiments are provided so that this disclosure will be thorough, and will convey the scope of the invention to those skilled in the art.

It will be understood that when an element or layer is referred to as being “on”, “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there may be no intervening elements or layers present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a”, “an” and “the” may be intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-section illustrations that may be schematic illustrations of idealized embodiments (and intermediate structures). As such, variations from the shapes of the illustrations as a result, for example, of manufacturing techniques and/or tolerances, are to be expected. Thus, the example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to limit the example embodiments.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

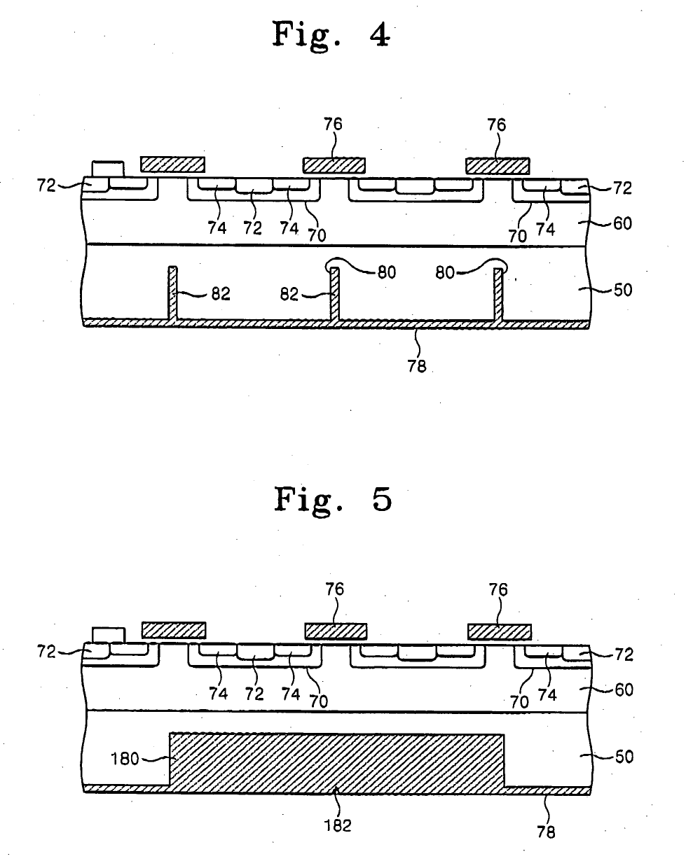

FIG. 4 is a cross-sectional view of a power semiconductor device according to an example embodiment.

Referring to FIG. 4, a power semiconductor device may include a drift region 60 formed on an upper surface of a semiconductor substrate 50. A body region 70 may be formed in the drift region 60. A source region 74 where impurities are diffused may be formed in the body region 70.

For example, the drift region 60 may be a region where charge may be drifted. The drift region 60 may be an n-type epitaxial layer doped at a lower concentration to increase a breakdown voltage in higher voltage operation. The semiconductor substrate 50 may be an n+substrate doped at a higher concentration relative to the n-type epitaxial layer 60.

The body region 70 may be a p-type body region in which p-type impurities may be diffused on a surface of the n-type epitaxial layer 60. The source 74 may be an n+source that may be formed in the p-type body region 70 and spaced apart from the n-type epitaxial layer 60. The source 74 may be connected with a source electrode (not shown), for example, an interconnection layer. The source electrode may be commonly connected with the source 74 and the body region 70. A p+pickup 72 connected with the source electrode may be formed in the body region 70.

A gate electrode 76 may be formed on an upper portion of the epitaxial layer 60. A gate insulator (not shown) may be interposed between the gate electrode 76 and the epitaxial layer 60. An edge of the gate electrode 76 may be aligned with an edge of the source 74 and the gate electrode 76 may overlap with the body region 70. The gate electrode 76 may be a pattern of parallel strips or a mesh pattern with rectangular cells formed over the epitaxial layer 60.

A drain electrode 78 may be formed on a bottom surface of the substrate 50. The n+substrate 50 may operate as a drain and the drain electrode 78 may cover the bottom surface of the substrate. The drain electrode 78 may have a part 82 extending to a predetermined or desired depth of the substrate. A trench 80 having a predetermined or desired depth may be formed on the bottom surface of the substrate 50. The extending part 82 of the drain electrode 78 may fill the trench 80 and extend to a predetermined or desired depth in the substrate 50. For example, a power semiconductor device may include a drain electrode 78 having a plurality of extending parts 82.

If a positive bias is applied to the gate electrode 76, an n-channel may be formed in the body region 70 that is overlapped by the gate electrode 76, and the n+source 74 and the drain electrode 78 may be electrically connected. Electrons may migrate to the drain electrode 78 from the n+source 74 through the epitaxial layer 60 and the substrate 50.

The electrons flowing to the drain electrode 78 may migrate to an edge of the extending part 82, which may be a shorter distance than to the bottom surface of the substrate 50. Accordingly, a migration distance of the electrons in the substrate 50 may be shortened and the resistance of the substrate resistor R_{sub} may be reduced. Because the migration distance (e.g. current path) may be shortened by the extending part 82 of the drain electrode 78, there may be less of a need to polish the substrate 50 to reduce the resistance of the substrate resistor R_{sub}. Accordingly, the substrate need not be overpolished, which may prevent or reduce the possibility that the wafer may be bent and/or the substrate may be cracked during subsequent processes.

The extending part 82 of the drain electrode 78 may be formed in the bottom portion the substrate 50 and may be spaced between the body regions 70. In this way, current I flowing between the sources 74 and the drain electrode 78 may flow through the shortest path. The extending part of the drain electrode 78 may be formed opposing the gate electrode 76. The shape of the drain electrode 78 may correspond to the shape of a source electrode (not shown) or the gate electrode 76. For example, in an example embodiment, where the gate electrode 76 may be a pattern of parallel strips, the extending part 82 may be a pattern of parallel fins. In an example embodiment, where the gate electrode 76 may be rectangular shaped projecting parts arranged in a mesh pattern, the extending parts 82 may be rectangular shaped projecting parts arranged in a mesh pattern. However, a shape of the extending part 82 of the drain electrode 78 is not limited to a shape of a gate electrode.

FIG. 5 is cross sectional view of a power semiconductor device according to an example embodiment.

Referring to FIG. 5, a wider trench 180 may be formed in the substrate 50. The drain electrode 78 may include an extending part 182 in the trench 180 so the drain electrode 78 may occupy a larger region in the substrate 50. The extending part 182 may allow the drain electrode 78 to extend closer to the epitaxial layer 60. In an example embodiment, a power semiconductor device may include a drain electrode 78 having a plurality of extending parts 182 that may occupy a larger region in the substrate 50.

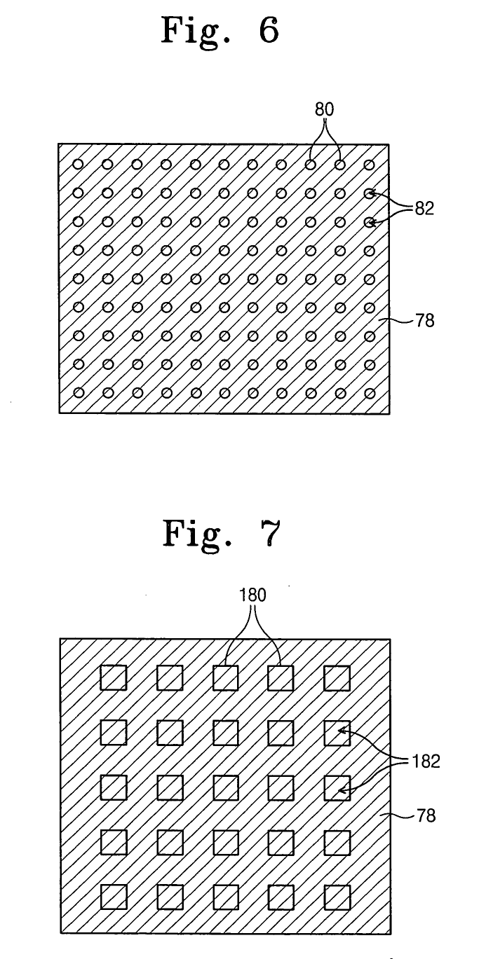

The drain electrode 78 may include a plate that covers a bottom surface of the substrate 50 and may include a variety of the extending parts 182. FIGS. 6 through 9 illustrate various shapes of the extending parts 182 of the drain electrode 78.

Referring to FIG. 6, the drain electrode 78 may include a plate that covers the bottom surface of the substrate 50. The drain electrode 78 may include a plurality of circular-shaped pins 82 extending to a predetermined or desired depth of the substrate 50 that may be arranged in rows and/or columns. As illustrated FIG. 4, the pins 82 may fill a trench 80 formed in the bottom surface of the substrate 50 and may extend toward the epitaxial layer 60.

Referring to FIG. 7, the drain electrode 78 may include a plate that covers the bottom surface of the substrate 50. The drain electrode 78 may include a plurality of rectangular projecting parts 182 extending to a predetermined or desired depth of the substrate 50 that may be arranged in row and/or column directions. As illustrated FIG. 5, the rectangular projecting parts 182 may fill the recessed trench 180 formed in the bottom surface of the substrate 50 and may extend toward the epitaxial layer 60.

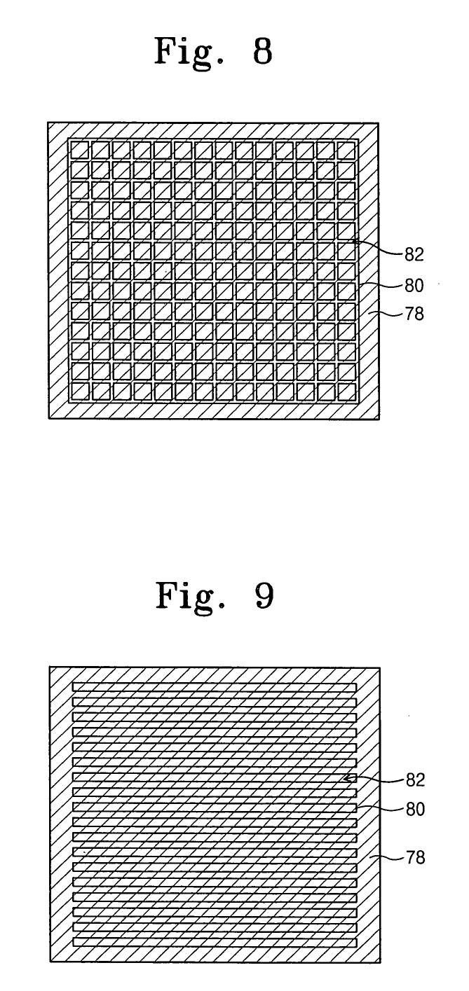

Referring to FIG. 8, the drain electrode 78 may include a plate that covers the bottom surface of the substrate. The drain electrode 78 may include a plurality of rectangular-shaped projecting parts 82 arranged in a mesh pattern and extending to a predetermined or desired depth of the substrate 50. Trenches 80 may be formed in the substrate 50 to correspond to each rectangular-shaped projecting part 82. The rectangular shaped projecting parts 82 of the drain electrode 78 may fill the trenches 80 and may extend toward the epitaxial layer 60.

Referring to FIG. 9, the drain electrode 78 may include a plate that covers the bottom surface of the substrate 50. The drain electrode 78 may include a plurality of parallel fins 82 extending to a predetermined or desired depth of the substrate 50. A plurality of trenches 80 having a parallel slit shape may be formed in the substrate 50. The fins 82 of the drain electrode 78 may fill the trenches 80 and may extend towards the epitaxial layer 60.

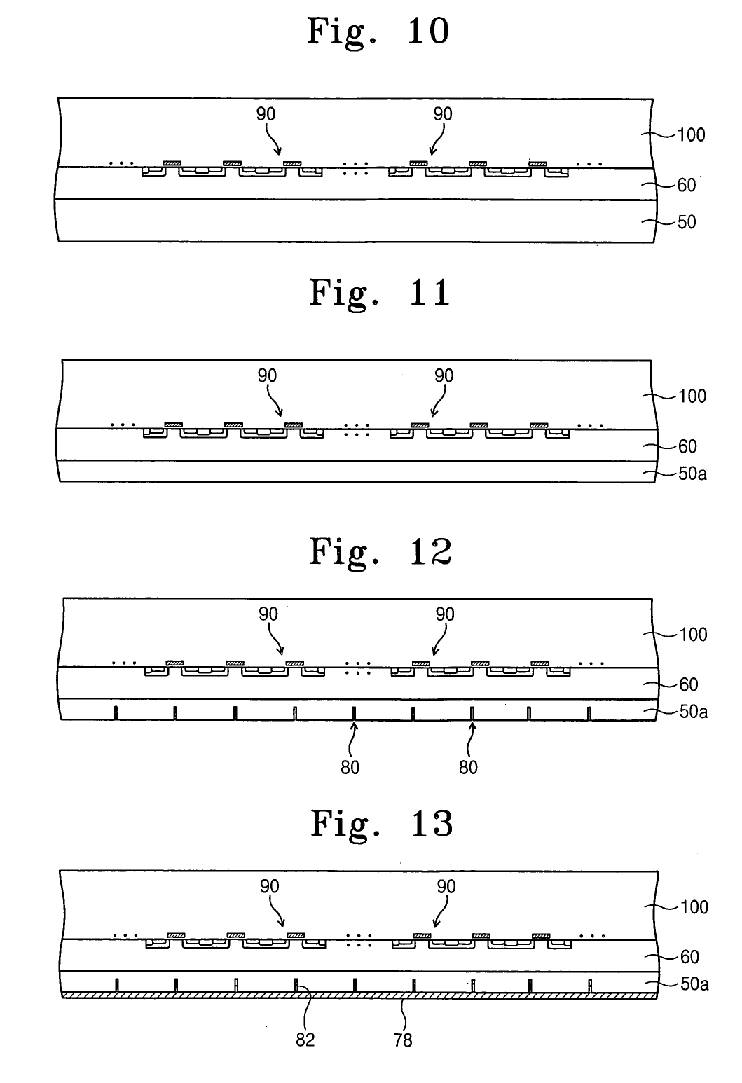

FIGS. 10 through 13 are cross sectional views of a method of fabricating a power semiconductor device according to an example embodiment.

Referring to FIG. 10, an n-type epitaxial layer 60 may be formed in an upper surface of an n+substrate 50. The epitaxial layer 60 may have a lower impurity concentration than the semiconductor substrate 50. P-type impurities may be diffused in the surface of the epitaxial layer 60 to form a body region 70. A gate electrode 76 may be formed on the epitaxial layer 60 that may partially overlap the body region 70. A gate insulator (not shown) may be interposed between the gate electrode 76 and the epitaxial layer 60. Impurities may be injected in the body region 70 around the gate electrode 76 to form an n+source 74 and a p+pickup 72 and an element region 90. In the epitaxial layer 60 in which the element region 90 is formed, a process of forming an interconnection (not shown) and an interlayer dielectric layer 100 may be performed to complete fabrication of the semiconductor.

In a conventional process, a substrate 50A may be polished to have a thickness between 80 to 150 micrometers to reduce the resistance of the substrate resistor R_{sub} . As a result, the wafer may bend, the substrate may crack, and/or it may be more difficult to treat a wafer in subsequent processes. Referring to FIG. 11, according to an example embodiment, the bottom surface of the substrate 50 may be polished to only partially reduce the thickness of the substrate 50. The substrate 50A may be polished to a thickness suitable for die cutting, so that it may be easier to dice the wafer.

Referring to FIG. 12, a trench 80 of a predetermined or desired depth may be formed by patterning the bottom surface of the polished substrate 50A. As described above, the trench 80 may be formed of various shapes, for example, circular shapes arranged in row and/or column directions, a plurality of parallel slit shapes, rectangular shapes, and rectangular shapes formed in a mesh pattern. For example, the trench 80 may also have a shape that may correspond to the shape of a source electrode (not shown) or the gate electrode 76.

Referring to FIG. 13, a drain electrode 78 may be formed in the bottom surface of the substrate 50A to fill the trench 80. The drain electrode 78 may be formed of metal, for example, aluminum, tantalum, and/or copper. The drain electrode 78 may fill the trench 80 and may have a projecting part 82 extending to a predetermined or desired depth of the substrate 50A. The trench 80 may have a width ranging from several micrometers to dozens of micrometers. If the width of the trench 80 is narrow or an aspect ratio is higher, the drain electrode 78 may be formed by a copper damascene process. Other conventional processes for forming the drain electrode 78 may be implemented, but a description thereof will be omitted because they are well known to a person of ordinary skill in the art.

As described above, according to example embodiments, a current path flowing through a substrate of a power semiconductor device may be shortened to reduce a resistance of a substrate resistor. Accordingly, an on-resistance of the power semiconductor device may be reduced.

Furthermore, according to example embodiments, the substrate of the power semiconductor device need not be overpolished to reduce the resistance of a substrate resistor. Accordingly, the possibility of the substrate cracking and/or the wafer bending during subsequent processes may be reduced or prevented.

What is claimed is:

1. A power semiconductor device, comprising:
a substrate having a first conductivity type;
a drift region having the first conductivity type at a lower concentration formed on an upper surface of the substrate;
a body region having a second conductivity type formed on an upper surface of the drift region;
a source region having the first conductivity type formed in the body region and spaced apart from the drift region;
a gate electrode formed on the upper surface of the drift region; and
a drain electrode formed on a bottom surface of the substrate and extending into the substrate to a depth.

2. The power semiconductor device of claim 1, wherein the drain electrode extends into the substrate to fill at least one trench formed in the bottom surface of the substrate.

3. The power semiconductor device of claim 1, wherein the drain electrode is a metal layer.

4. The power semiconductor device of claim 1, wherein the drain electrode includes a plate covering the bottom surface of the substrate and at least one vertical extension that extends to a depth in the substrate.

5. The power semiconductor device of claim 4, wherein the at least one vertical extension is a plurality of circular shaped pins.

6. The power semiconductor device of claim 4, wherein the at least one vertical extension is a plurality of rectangular shaped projecting parts.

7. The power semiconductor device of claim 4, wherein the at least one vertical extension is plurality of rectangular shaped projecting parts arranged in a mesh pattern.

8. The power semiconductor device of claim 4, wherein the at least one vertical extension is a plurality of fins arranged in parallel.

9. The power semiconductor device of claim 4, wherein the vertical extension is formed opposed to the gate electrode.

10. The power semiconductor device of claim 4, wherein the vertical extension is in a shape corresponding to the shape of the gate electrode.

11. The power semiconductor device of claim 1, wherein an edge of the gate electrode is aligned with the source region and the gate electrode overlaps the body region.

12. The power semiconductor device of claim 1, wherein the first conductivity type is n-type and the second conductivity type is a p-type.

13. The power semiconductor device of claim 1, wherein the drift region is an epitaxial layer formed on the upper surface of the substrate.

14. A method of fabricating a power semiconductor device, comprising:
forming a drift region on an upper surface of a semiconductor substrate;
forming a body region at an upper surface of the drift region;
forming a source region in the body region;
forming a gate electrode having at least one edge aligned with an edge of the source region and overlapping the body region;
forming at least one trench in the bottom surface of the semiconductor substrate; and
forming a drain electrode on the bottom surface of the semiconductor substrate to fill the trench.

15. The method of claim 14, further comprising forming a gate insulator between the drift region and the gate electrode.

16. The method of claim 14, further comprising polishing a bottom surface of the substrate to reduce a thickness of the substrate, wherein the at least one trench is formed at a bottom surface of the substrate having a reduced thickness.

17. The method of claim 14, wherein forming the at least one trench includes forming a plurality of trenches having a circular shape and arranged in at least one of rows and columns.

18. The method of claim 14, wherein forming the at least one trench includes forming a plurality of trenches having a rectangular shape and arranged in at least one of rows and columns.

19. The method of claim 14, wherein forming the at least one trench includes forming a plurality of trenches having a rectangular shape and arranged in a mesh pattern.

20. The method of claim 14, wherein forming the at least one trench includes forming a plurality of trenches in the shape of a strip and arranged in parallel.

21. The method of claim 14, wherein the drain electrode is a metal layer.
